(19) United States
(12) Patent Application Publication
(10) Pub. No.: US 2011/0232569 A1
(43) Pub. Date: Sep. 29, 2011

(54) SEGMENTED SUBSTRATE LOADING FOR MULTIPLE SUBSTRATE PROCESSING

(75) Inventor: DONALD OLGADO, Palo Alto, CA (US)

(73) Assignee: APPLIED MATERIALS, INC., Santa Clara, CA (US)

(21) Appl. No.: 13/052,725

(22) Filed: Mar. 21, 2011

Related U.S. Application Data
(60) Provisional application No. 61/317,638, filed on Mar. 25, 2010.

(51) Int. Cl. H01L 21/677; C23C 16/458; C23C 16/44; H01L 21/68; H01L 21/687

(52) U.S. Cl. 118/719; 414/222.01; 414/806

(57) ABSTRACT

Embodiments of the present invention provide apparatus and methods for loading and unloading a multiple-substrate processing chamber segment by segment. One embodiment of the present invention provides an apparatus for processing multiple substrates. The apparatus includes a substrate supporting tray having a plurality of substrate pockets forming a plurality of segments, and a substrate handling assembly configured to pick up and drop off substrates from and to a segment of substrate pockets of the substrate supporting tray.

### CROSS REFERENCE TO RELATED APPLICATION

This application claims benefit of the U.S. Provisional Patent Application Ser. No. 61/317,638, filed Mar. 25, 2010, which is incorporated herein by reference.

### BACKGROUND OF THE INVENTION

1. Field of the Invention

Embodiments of the present invention relate to apparatus and methods for handling substrates during processing. More particularly, embodiments of the present invention relate to apparatus and methods for loading substrates into processing chambers that simultaneously process multiple substrates, for example, processing chambers for manufacturing devices such as light emitting diodes (LEDs), laser diodes (LDs), and power electronics.

2. Description of the Related Art

When processing small substrates during semiconductor processing, a plurality of substrates are often loaded into substrate carriers then transferred in and out of processing chambers with substrate carriers. For example, sapphire substrates used in manufacturing of light emitting diodes (LED) are usually processed in a batch mode with a batch of sapphire substrates disposed and transferred in a substrate carrier during processing.

However, using substrate carriers affects repeatability of processing chambers since different substrate carriers affect performance of the processing chambers differently. Using substrate carriers also limits productivity in various ways. First, the size of substrate carriers is limited by method for manufacturing and the size of slit valve doors in a processing system. Since substrate carriers are usually formed from silicon carbide to obtain desired properties, it is difficult and expensive to manufacture substrate carriers beyond 0.5 meter in diameter. Therefore, even though chambers are capable of processing more substrates at the same time, the number of substrates processed is limited by the size of the substrate carriers used. Second, cost of production is increased because substrate carriers are subject to substantive wear during processing as substrate carriers are transferred with the substrates among various chambers, loading stations, load locks, and exposed to various environments. Additionally, using substrate carriers also requires robots for handling the substrates during loading, unloading, landing, and robots for handling the substrate carriers, thus, also increasing the cost of production.

Therefore, there is a need for method and apparatus for handling substrates during multiple substrate processing.

### SUMMARY OF THE INVENTION

Embodiments of the present invention relate to apparatus and methods for loading substrates into processing chambers that simultaneously process multiple substrates. More particularly, embodiments of the present invention provide apparatus and methods for loading and unloading a processing chamber in a segment by segment manner.

One embodiment of the present invention provides an apparatus for processing multiple substrates. The apparatus includes a chamber body defining a processing volume and a substrate supporting tray disposed in the processing volume. The chamber body has a first opening to allow passage of substrates therethrough. The substrate supporting tray has a plurality of substrate pockets formed on an upper surface. Each substrate pocket accommodates a substrate therein. The plurality of substrate pockets form a plurality of segments. The apparatus further includes a substrate handling assembly disposed in the processing volume. The substrate handling assembly moves relative to the substrate supporting tray to pick up and drop off substrates from and to a segment of substrate pockets in a loading position aligned with the substrate handling assembly. Each of the plurality of segments is alignable with the substrate handling assembly.

Another embodiment of the present invention provides a cluster tool for processing multiple substrates including a first processing chamber. The cluster tool also includes a transfer chamber selectively connected to the first processing chamber via a first opening of the first processing chamber, and a substrate transfer robot disposed in the transfer chamber to load and unload substrates in the first processing chamber. The substrate transfer robot includes a first robot blade having one or more substrate pockets. The one or more substrate pockets in the first robot blade are arranged in the same pattern as the one or more substrate pockets in each segment on a first substrate supporting tray of the first processing chamber.

Yet another embodiment of the present invention provides a method for handling substrates during multiple-substrate processing. The method includes receiving one or more substrates in a first segment of a substrate supporting tray in a multiple-substrate processing chamber from an exterior substrate transfer robot. The multiple-substrate processing chamber includes features as described above. The method also includes rotating the substrate supporting tray to align a second segment of the substrate supporting tray with the substrate handling assembly, and receiving one or more substrates in the second segment of the substrate supporting tray from the exterior substrate transfer robot.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a plan view of a cluster tool including multiple-substrate processing chambers in accordance with one embodiment of the present invention.

FIG. 2A is a schematic top view of a multiple-substrate processing chamber and a substrate transfer robot in accordance with one embodiment of the present invention.

FIG. 2B is a schematic sectional view of the multiple-substrate processing chamber of FIG. 2A in a substrate transfer position.

FIG. 2C is a schematic top view of the multiple-substrate processing chamber with a substrate carrier removed.

FIG. 2D is a schematic sectional view of the multiple-substrate processing chamber of FIG. 2A in a segment switching position.

FIG. 3A is a schematic perspective view of a substrate grabbing assembly according to one embodiment of the present invention.

FIG. 3B is a partial top view of a substrate supporting tray in accordance with one embodiment of the present invention.

FIG. 4A is a partial sectional view of a substrate supporting tray carrier according to one embodiment of the present invention.

FIG. 4B is a partial sectional view of the substrate supporting tray of FIG. 4A receiving a lifting pin.

FIG. 5A is a schematic top view of a substrate carrier using sub-carriers to process smaller substrates.

FIG. 5B is a partial sectional view of the substrate carrier of FIG. 5A.

FIG. 6 is a schematic top view of a substrate processing system having a transfer robot adapted to transfer two substrates simultaneously in accordance with one embodiment of the present invention.

FIG. 7 is a schematic top view of a substrate processing system having a transfer robot adapted to transfer multiple substrates simultaneously in accordance with one embodiment of the present invention.

FIG. 8 is a plan view of a cluster tool including multiple-substrate processing chambers in accordance with one embodiment of the present invention.

FIG. 9 is a plan view of a cluster tool including multiple-substrate processing chambers in accordance with another embodiment of the present invention.

FIG. 10 is a plan view of a liner cluster tool for multiple-substrate processing in accordance with one embodiment of the present invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention provide apparatus and methods for loading and unloading a processing chamber configured to process multiple substrates. More particularly, embodiments of the present invention provide apparatus and methods for loading and unloading a processing chamber in a segment by segment manner. Embodiments of the present invention also provide apparatus and methods for transferring multiple substrates in and out a processing chamber without transferring substrate supporting trays in and out the processing chamber.

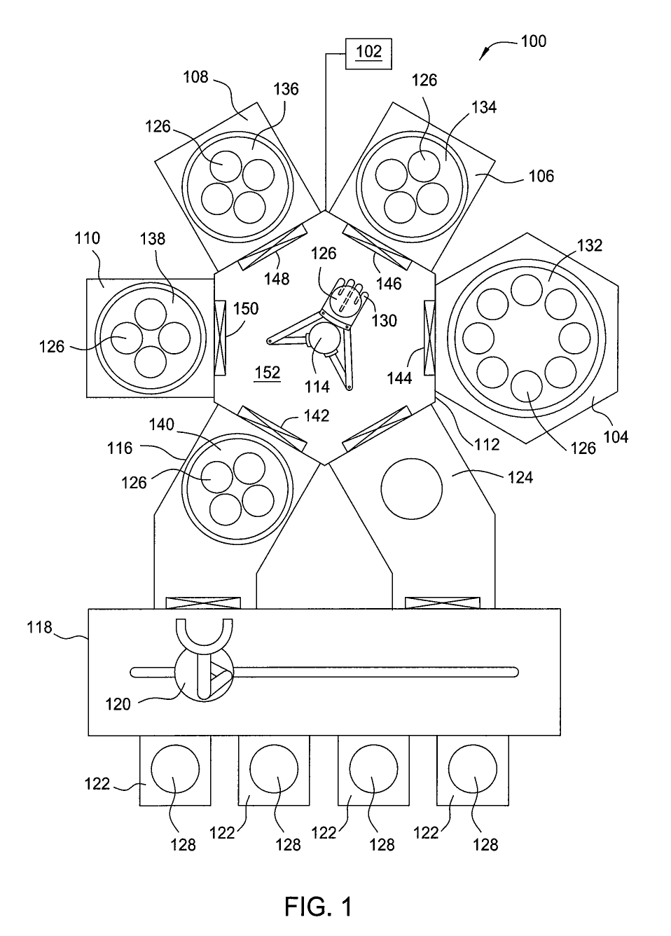

FIG. 1 is a plan view of a cluster tool 100 for multiple-substrate processing in accordance with one embodiment of the present invention. The cluster tool 100 generally creates a processing environment where various processes can be performed to a substrate. In one embodiment, the cluster tool 100 is to fabricate compound nitride semiconductor devices, such as such as light emitting diodes (LEDs), a laser diodes (LDs), and power electronics. The cluster tool 100 generally include a system controller 102 programmed to carrier out various processes performed in the cluster tool 100.

The cluster tool 100 includes a plurality of processing chambers 104, 106, 108, 110 coupled to a transfer chamber 112. Each processing chamber 104, 106, 108, 110 is configured to process multiple substrates 126 simultaneously. The processing chamber 104, 106, 108, 110 may have different substrate processing capacities. For example, the processing chamber 104 can simultaneously process twice as many substrates as the processing chambers 106, 108, 110 can.

The cluster tool 100 also includes a load lock chamber 116 connected to the transfer chamber 112. In one embodiment, the cluster tool 100 also includes one or more service chambers 124 coupled to the transfer chamber 112 for providing various functions for processing, for example, substrate orientation, substrate inspection, heating, cooling, degassing, or the like. The transfer chamber 112 defines a transfer volume 152. A substrate transfer robot 114 is disposed in the transfer volume 152 for transferring substrates 126 among the processing chambers 104, 106, 108, 110, the load lock chambers 116, and optionally the service chamber 124. The transfer volume 152 is in selective fluid communication with the processing chambers 104, 106, 108, 110, the load lock chambers 116 via slit valves 144, 146, 148, 150, 142 respectively.

The cluster tool 100 includes a factory interface 118 connecting one or more pod loaders 122 and the load lock chamber 116. The load lock chamber 116 provides a first vacuum interface between the factory interface 118 and the transfer chamber 112, which may be maintained in a vacuum state during processing. Each pod loader 122 is configured to accommodate a cassette 128 for holding and transferring a plurality of substrates. The factory interface 118 includes a FI robot 120 configured to shuttle substrates between the load lock chamber 116 and the one or more pod loaders 122.

The substrate transfer robot 114 includes a robot blade 130 for carrying one or more substrates 126 among the processing chambers 104, 106, 108, 110, the load lock chamber 116, and the service chamber 124, and loading/unloading each chamber.

Each processing chamber 104, 106, 108, 110 include a substrate supporting tray 132, 134, 136, 138 respectively. Each substrate supporting tray 132, 134, 136, 138 is configured to support multiple substrates 126 in the respectively processing chamber 104, 106, 108, 110 during processing. During processing, the substrate supporting trays 132, 134, 136, 138 remain in the respectively processing chambers and do not travel with the substrates 126 among the processing chambers. In one embodiment, the load lock chamber 116 may also include a stay-in substrate supporting tray 140 similar to the substrate supporting trays 132, 134, 136, 138 in the processing chambers 104, 106, 108, 110. In the exemplary embodiment shown in FIG. 1, the substrate supporting tray 132 is configured to hold 8 substrates that are 6 inches in diameter, and the substrate supporting trays 134, 136, 138, 140 are configured to hold 4 substrates that are 6 inches in diameter. Different substrate supporting trays can be used when processing substrates of different sizes, such as substrates that are 2 inches in diameter, 4 inches in diameter or 8 inches in diameter.

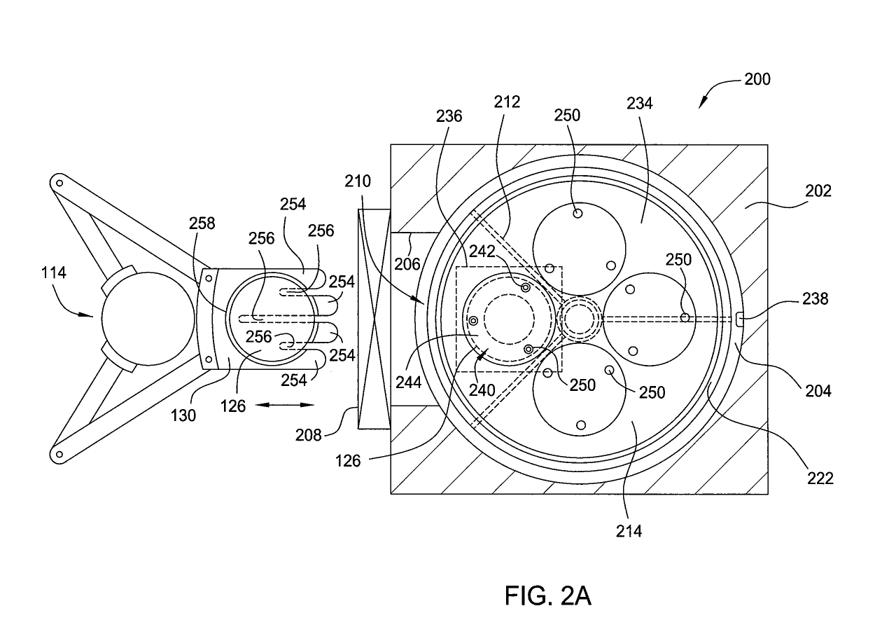

According to embodiments of the present invention, each of the processing chambers 104, 106, 108, 110 can be loaded or unloaded by the substrate transfer robot 114 in a segmented manner. The substrate transfer robot 114 is configured to retrieve substrates 126 from or deliver substrates 126 to a segment of each the processing chambers 104, 106, 108, 110. Particularly, the substrate transfer robot 114 can load or unload a segment of the substrate supporting trays 132, 134, 136, 138 in one trip. One or more substrates 126 may be in each segment of the substrate supporting trays 132, 134, 136, 138. Each processing chambers 104, 106, 108, 110 is loaded or unloaded by multiple trips of the substrate transfer robot 114. After loading and/or unloading one segment, the substrate supporting trays 132, 134, 136, 138 may move to align a new segment with the substrate transfer robot 114 to repeat the loading and/or unloading until the entire chamber is loaded and/or unloaded. Details on embodiments of processing chambers and substrate transfer robots that enable segmented loading are further described with FIGS. 2-7 below.

Segmented loading allows the substrate transfer robot 114 to be compatible with processing chambers of different capacities. Each segment of the substrate supporting trays 132, 134, 136, 138 may include a number of substrates that can be transferred by the substrate transfer robot 114 at one time. For example, in the embodiment shown in FIG. 1, the robot blade 130 of the substrate transfer robot 114 carries one substrate at a time, and each segment in the substrate supporting trays 132, 134, 136, 138 includes one substrate, and the processing chambers 104, 106, 108, 110 are loaded/unloaded in 4 and 8 segments. However, chamber capacity and segment arrangement can be modified according to various factors, such as the size of the substrates being processed and the processing recipes.

In one embodiment, the cluster tool 100 is configured to manufacture light emitting diodes (LED) and the processing chambers 104, 106, 108, 110 are metal organic chemical vapor deposition (MOCD) chambers and/or hydride vapor phase epitaxy (HVPE) chambers configured to form group-III nitride films.

A LED device is generally formed by a stack of films including: an n-GaN (n-doped GaN) layer, a MQW (multi quantum well) layer, p-GaN layer (including p-doped AlGaN layer and a p-doped GaN layer) on a substrate. All layers can be formed by MOCVD. When using MOCVD, the n-GaN layer and the MQW layer take longer to form that the p-GaN layer. Alternatively, the n-GaN layer may be formed using HVPE to achieve a fast growth rate. Embodiments of the present invention include arrangements of processing chambers in a cluster tool to achieve overall efficiency when fabricating LED devices.

In one embodiment, the cluster tool 100 is configured to form LED devices on substrates using MOCVD to consecutively form an n-GaN layer, a MQW layer, and p-GaN layer on a substrate. Particularly, the processing chamber 104, which has twice the substrate processing capacity as the processing chambers 106, 108, 110, is a MOCVD chamber configured to form n-GaN layers on the substrates 126; the processing chambers 106, 108 are MOCVD chambers configured to form MQW layers on the substrates 126; and the processing chamber 110 is a MOCVD chamber configured to form p-GaN layers on the substrates 126. By assigning the large processing chamber 104 to the n-GaN deposition process and two processing chambers 106, 108 to the MQW deposition process, this arrangement reduces waiting time between processes and increases efficiency.

During processing, substrates 126 being processed in a cassette 128 is first loaded into one of the pod loaders 122. The FI robot 120 then picks up the substrates 126 from the pod loader 122 and transfers the substrate 126 to the substrate supporting tray 140 in the load lock chamber 116. Alternatively, FI robot 120 may transfer the cassette 128 into the load lock chamber 116 when the substrate supporting tray 140 is not present in the load lock chamber 116. The load lock chamber 116 with the substrates 126 on the substrate supporting tray 140 or in the cassette 128 is sealed and pumped up to the environment close to that of the transfer chamber 112. The slit valve 142 between the load lock chamber 116 and transfer chamber 112 is then opened so that the substrate transfer robot 114 can pick up the substrate 126 in the load lock chamber 116.

The substrate transfer robot 114 extends the robot blade 130 into the load lock chamber 116, picks up a substrate 126 therein, and retracts the robot blade 130 with the substrate 126 to the transfer volume 152. The substrate transfer robot 114 then rotates and aligns the robot blade 130 with the processing chamber 104 to load the substrate 126 in the processing chamber 104. Optionally, the substrate transfer robot 114 may first transfer the substrates 126 to the service chamber 124 for alignment, preheating, cleaning or inspection before loading the substrate 126 to the processing chamber 104.

The robot blade 130 extends into the processing chamber 104 through the slit valve 144 which is open while the substrate supporting tray 132 rotates to align one segment with the substrate transfer robot 114 to receive the substrate 126. One substrate is loaded in the processing chamber 104. The substrate transfer robot 114 repeats picking up a substrate 126 from the load lock chamber 116 and loading the substrate 126 to the processing chamber 104 to load the processing chamber 104 segment by segment until the processing chamber 104 is full.

The slit valve 144 then closes and a process to deposit an n-GaN layer on the substrates 126 is performed in the processing chamber 104. After the process in the processing chamber 104 is completed, the processing chamber 104 is pumped out and the slit valve 144 opens. The substrate transfer robot 114 retrieves the substrates 126 with the n-GaN layer from the processing chamber 104 and transfers the substrate 126 with the n-GaN layer to the processing chamber 106 and 108 segment by segment, or one by one in the configuration shown in FIG. 1.

After each processing chamber 106, 108 is loaded with substrates 126 having n-GaN layer, the slit valve 146, 148 closes and a process to deposit a MQW layer on the substrates 126 is performed in each processing chamber 106, 108. While the MQW deposition is going in the processing chambers 106, 108, the substrate transfer robot 114 can reload the processing chamber 104 with a new batch of substrates 126 to begin processing to the new batch of substrates 126.

After the process in the processing chamber 106 is completed, the processing chamber 106 is pumped out and the slit valve 146 opens. The substrate transfer robot 114 retrieves the substrates 126 with the MQW layer from the processing chamber 106 and transfers the substrates 126 with the MQW layer to the processing chamber 110 segment by segment.

A process to deposit a p-GaN layer on the substrates 126 is then performed in the processing chamber 110. After the p-GaN layer deposition is completed, the processing chamber 110 is pumped out and the substrate transfer robot 114 transfers the substrates 126 with the p-GaN layer to the load lock chamber 116. Optionally, the substrates 126 may be transferred to the service chamber 124 for cooling, or examination before going back to the load lock chamber 116.

The substrates 126 from the processing chamber 108 are then transferred to the processing chamber 110 for deposition of a p-GaN layer. The processed substrates 126 are then transferred out of the processing chamber 110 to the load lock chamber 116.

The FI robot 120 transfers the processed substrates 126 from the load lock chamber 116 to the pod loader 122, where the processed substrates 126 can be transferred or stored for further processes.

It should be noted that the cluster tool 100 can be modified to perform various processes by exchanging or programming the one or more processing chambers.

For example, in an alternative embodiment, the processing chambers 104, 106, 108, 110 can be arranged to enable the cluster tool 100 to form GaN templates for LED devices by depositing an n-GaN layer on a substrate.

In another embodiment, the processing chambers 104, 106, 108, 110 can be arranged to enable the cluster tool 100 to form LED devices on n-GaN templates by forming a multi quantum well (MQW) layer, p-doped AlGaN layer, and a p-GaN (p-doped GaN) layer on GaN templates.

In yet another alternative embodiment, the processing chambers 106, 108 are MOCVD chambers configured to form n-GaN layer; the processing chamber 104 is a MOVCVD chamber configured to form MQW layers; and the processing chamber 110 is a MOCVD chamber configured to form p-GaN layers on the substrates 126.

FIG. 2A is a schematic top view of a multiple-substrate processing chamber 200 in accordance with one embodiment of the present invention. FIG. 2B is a schematic sectional view of the multiple-substrate processing chamber 200. The multiple-substrate processing chamber 200 is configured to be loaded and unloaded in a segmented manner. The multiple substrate processing chamber 200 may be used in place of the one of the processing chambers 104, 106, 108, 110 in the cluster tool 100 of FIG. 1.

The multiple substrate processing chamber 200 comprises a chamber body 202 defining a processing volume 204. The chamber body 202 has an opening 206 formed therethrough to allow passage of substrates to and from an processing volume 204. The opening 206 may be selective closed, for example by a slit valve door 208. A robot, such as the substrate transfer robot 114 can be used to transfer substrates 126 in and out the multiple substrate processing chamber 200.

A substrate supporting assembly 210 is disposed in the processing volume 204 for supporting a plurality of substrates 126 during processing. The substrate support assembly 210 includes a rotating frame 212 and a substrate supporting tray 214 disposed on the rotating frame 212.

In one embodiment, the multiple substrate processing chamber 200 is a MOCVD chamber having a showerhead assembly 224 disposed above the substrate supporting assembly 210 and a heat source 228 disposed below a quartz bottom 226.

The rotating frame 212 includes a shaft 216 coupled to an actuator 218 configured to rotate and vertically move the shaft 216. Two or more fingers 220 extend from the shaft 216 to a supporting ring 222 on which the substrate supporting tray 214 sits. The fingers 220 are usually slim, thus allowing a back side of the substrate supporting tray 214 exposed to the heat source 228 disposed below.

The substrate supporting tray 214 is a thin plate having a plurality of substrate pockets 230 formed on an upper surface 234. Each substrate pocket 230 is configured to accommodate a substrate 126. The plurality of substrate pockets 230 can be grouped in a plurality of segments, wherein the substrate pockets 230 in each segment are arranged in the same pattern to enable segmented loading/unloading. In one embodiment, each segment may include one substrate pocket 230.

Each substrate pocket 230 is configured to accommodate one substrate. In one embodiment, the substrate supporting tray 214 is circular and shaft 216 rotates the substrate supporting tray 214 about a center axis 232. The substrate pockets 230 are arranged on the upper surface 234 of the substrate supporting tray 214 so that every substrate pocket 230 can be positioned in a loading position 236 as the substrate supporting tray 214 rotates about the center axis 232. The substrates 126 in the substrate pockets 230 are uniformly exposed to the processing environment as the substrate supporting tray 214 rotates.

In one embodiment, the substrate pockets 230 may be evenly distributed on the substrate supporting tray 214 in one circular pattern and one substrate pocket 230 can be aligned in the loading position 236 at a time as shown in FIG. 2A. However, depending on the size of the processing volume 204 and the diameter of the substrates 126, the substrate pockets 230 may be arranged accordingly to improve throughput and to insure process uniformity.

The substrate supporting tray 214 may be removably disposed on the rotating frame 212 and may be exchanged and removed for maintenance. In one embodiment, the substrate supporting tray 214 is formed from a silicon carbide for supporting sapphire substrates.

In one embodiment, the multiple substrate processing chamber 200 includes a sensor assembly 238 configured to detect the orientation of the substrate supporting tray 214 and align one or more substrate pockets 230 with the loading position 236. The sensor assembly 238 may be optical sensors, or image sensors to detect a marker on the substrate supporting tray 214.

The multiple substrate processing chamber 200 further includes a lift pin assembly 240 disposed below the substrate supporting tray 214. The lift pin assembly 240 includes three or more lift pins 242 attached to a lift pin frame 244. The lift pin frame 244 is mounted on a lift pin shaft 246 through a mounting arm 252.

In one embodiment, three or more pin holes 250 are formed through the substrate supporting tray 214 in each substrate pocket 230. The pin holes 250 allows the lift pins 242 to be inserted therein for loading and unloading a substrate 126 when the substrate pocket 230 is in the loading position 236.

The lift pin assembly 240 is positioned below the loading position 236 to so that the lift pins 242 can pick up a substrate 126 from and drop off a substrate 126 onto a substrate pocket 230 in the loading position 236 as shown in FIG. 2B. The robot blade 130 includes supporting fingers 254 separated by slots 256 for accommodating lift pins 242 when the robot blade 130 enters the multiple substrate processing chamber 200. The supporting fingers 254 form a substrate pocket for holding a substrate 126 therein.

At least one of the lift pin frame 244 and the substrate supporting tray 214 can move vertically to allow the lift pins 242 to be inserted in the substrate supporting tray 214. In one embodiment, the lift pin assembly 240 is fixedly disposed in the processing volume 204 and the vertical motion of the substrate supporting tray 214 allows the lift pins 242 to move in and out the substrate supporting tray 214. In another embodiment, the lift pin shaft 246 is coupled to an actuator 248 configured to move the lift pins 242 vertically relative to the substrate supporting tray 214.

The loading position 236 may be near the opening 206 so that an exterior robot blade, such as the robot blade 130 of the substrate transfer robot 114 can pick up and drop off one or more substrates 126 from/into the substrate pockets 230 in the loading position 236. Because each substrate pocket 230 can be rotated to the loading position 236, the substrate transfer robot 114 only needs to have a range of motion to reach as far as the loading position 236 to have access to the entire substrate supporting tray 214. Therefore, embodiments of the present invention allow the multiple substrate processing chamber 200 to have a size larger than the size limited by the robot range, therefore, enabling increase in throughput.

As shown in FIG. 2A, since it is not necessary to move the substrate supporting tray 214 through the opening 206, the substrate supporting tray 214 can have a diameter much larger than the width of the opening 206, therefore, allowing increase in the number of substrates 126 being processed.

FIG. 2C is a schematic top view of the multiple-substrate processing chamber 200 with the substrate supporting tray 214 removed. The lift pin frame 244 may be a ring having three lift pins 242 extending therefrom.

FIG. 2D is a schematic sectional view of the multiple-substrate processing chamber 200 in a position where the substrate supporting tray 214 is above the lift pins 242. In this position, the substrate supporting tray 214 can rotate about the central axis 232 to switch segment that aligns with the lift pin assembly 240. The substrates 126 are also processed in the position shown in FIG. 2D.

During substrate transferring, the shaft 216 rotates the substrate supporting tray 214 to position an empty substrate pocket 230 in the loading position 236. The substrate transfer robot 114 extends the blade 130 to the multiple substrate processing chamber 200 and position the substrate 126 above the empty substrate pocket 230 in the loading position 236. The lift pins 242 moves up through the pin holes 250 in the substrate supporting tray 214 and the slots 256 in the blade 130 to pick up the substrate from a substrate pocket 258 of the blade 130. The robot blade 130 retracts without the substrate. The lift pins 242 then lower down below the substrate supporting tray 214 dropping the substrate in the substrate pocket 230 in the loading position 236.

The substrate transfer robot 114 may then go back to a load lock chamber or a different processing chamber to pick up a new substrate for processing in the multiple substrate processing chamber 200. The substrate supporting tray 214 rotates to have another empty substrate pocket 230 aligned with the loading position 236. The substrate transfer robot 114 then loads the substrate to the substrate supporting tray 214. The process can be repeated until the substrate supporting tray 214 is full. The slit valve door 208 may then be closed and the substrates on the substrate supporting tray 214 will be processed in the closed environment of the processing volume 204 in the multiple substrate processing chamber 200. During processing, the substrate supporting tray 214 may rotate constantly to ensure the multiple substrates on the substrate supporting tray 214 have uniform exposure to the processing environment, thus, being processed uniformly.

After the processing in the multiple substrate processing chamber 200 is completed, the multiple substrate processing chamber 200 is pumped out and the slit valve door 208 opens. The substrate supporting tray 214 positions one substrate pocket 230 in the loading position 236 and stops rotating. The lift pins 242 come through the pins holes 250 and pick up the substrate. The substrate transfer robot 114 then extends the robot blade 130 into the multiple substrate processing chamber 200 to below the substrate on the lift pins 242. The lift pins 242 then retract to below the substrate supporting tray 214 dropping the substrate on the robot blade 130. The robot blade 130 then retracts with the substrate and one substrate is unloaded from the multiple substrate processing chamber 200. The unloaded substrate may be transferred to a load lock chamber or another processing chamber for further processing. The substrate supporting tray 214 then rotates to align another substrate pocket 230 with a substrate with the loading position 236 to unload another substrate. The process is repeated until the substrate supporting tray is empty.

Any suitable substrate handling mechanisms may be used in place of the lift pin assembly 240 in the multiple substrate processing chamber 200 to achieve segmented loading. For example, the multiple substrate processing chamber 200 may include a substrate handling mechanism that uses vacuum methods, Bernoulli chucks, electrostatic chucks, or edge grabbing to pick up one or more substrates 126 from the substrate pockets 230 and exchange substrates 126 with exterior substrate handler, such as the robot 114.

In an alternative embodiment, the lift pin assembly 240 may be omitted in the multiple substrate processing chamber 200 wherein substrates 126 may be loaded and unloaded by an exterior substrate handler that can directly pick up the substrates 126 from the substrate pockets 230. For example, exterior substrate handler using edge grabbing, vacuum methods, Bernoulli chucks, or electrostatic chucks can be used for loading and unloading the multiple substrate processing chamber 200 without the lift pin assembly 240.

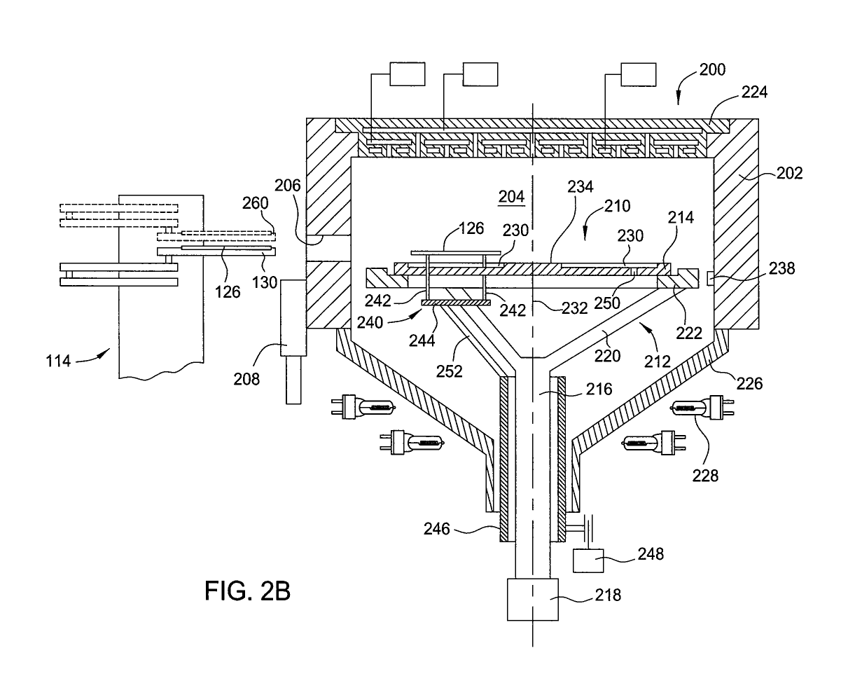

FIG. 3A is a schematic perspective view of a substrate grabbing assembly 300 according to one embodiment of the present invention. The substrate grabbing assembly 300 may include three or more grabbing fingers 302 attached to a frame 312. In one embodiment, the frame 312 may be attached to a shaft 316 through a mounting arm 314 for using in a processing chamber in which the area under the substrate grabbing assembly 300 is not available for mounting.

Each grabbing finger 302 may be extending vertically upwards from the frame 312. A top portion 318 of each grabbing finger 302 has a supporting surface 304 and a substrate directing surface 306 extending upwards and outwards from the supporting surface 304. The supporting surface 304 is configured for supporting a backside of a substrate near an edge area. The supporting surfaces 304 may be planar. The supporting surfaces 304 of the three or more grabbing fingers 302 form a substrate sitting area 308 where a substrate is supported by the three or more grabbing fingers 302. The substrate directing surface 306 is configured for directing the substrate to the substrate sitting area 308.

The grabbing fingers 302 may be arranged in a manner that each grabbing finger 302 contacts a substrate at the corresponding supporting surface 304 when a substrate is fully engaged with the substrate grabbing assembly 300. The directing surface 306 may be a sloped surface that flares outwards and upwards. The directing surfaces 306 define a receiving area 310 that is larger than the substrate being received, and gently direct the substrate down to the substrate sitting area 308. The substrate grabbing assembly 300 is especially usefully when in centering the substrate and aligning the substrate with a substrate pocket.

FIG. 3B is a partial top view of a substrate supporting tray 330 to be used with the grabbing mechanism 300. The substrate grabbing assembly 300 may be disposed under a substrate supporting tray 330 and the grabbing fingers 302 be actuated by an actuator and move relative to the substrate supporting tray 330.

The substrate supporting tray 330 is similar to the substrate supporting tray 214 except that each substrate pocket 332 of the substrate supporting tray 330 has three or more through holes 334 formed one an edge 336 of each substrate pocket 332. Each through hole 334 allows passage of one substrate grabbing finger 302. As illustrated in FIG. 3B, the substrate receiving area 310 defined by the grabbing fingers 302 is larger than the substrate pocket 332, and the substrate sitting area 308 is within the substrate pocket 332. Therefore, the substrate grabbing assembly 300 ensures that a substrate stays within the substrate pocket 332 when dropping a substrate into the substrate pocket 332.

As discussed above, in some processing chambers, such as MOCVD and HVPE chambers, one or more heating element may be positioned above and/or below a substrate supporting tray to heat the substrate supporting tray 214 and the substrates during processing. In the case where heating lamps or other heating elements are used to heat a substrate supporting tray from underneath the substrate supporting tray, a cap may be used in each pin holes to avoid direct heating to the substrate being processed.

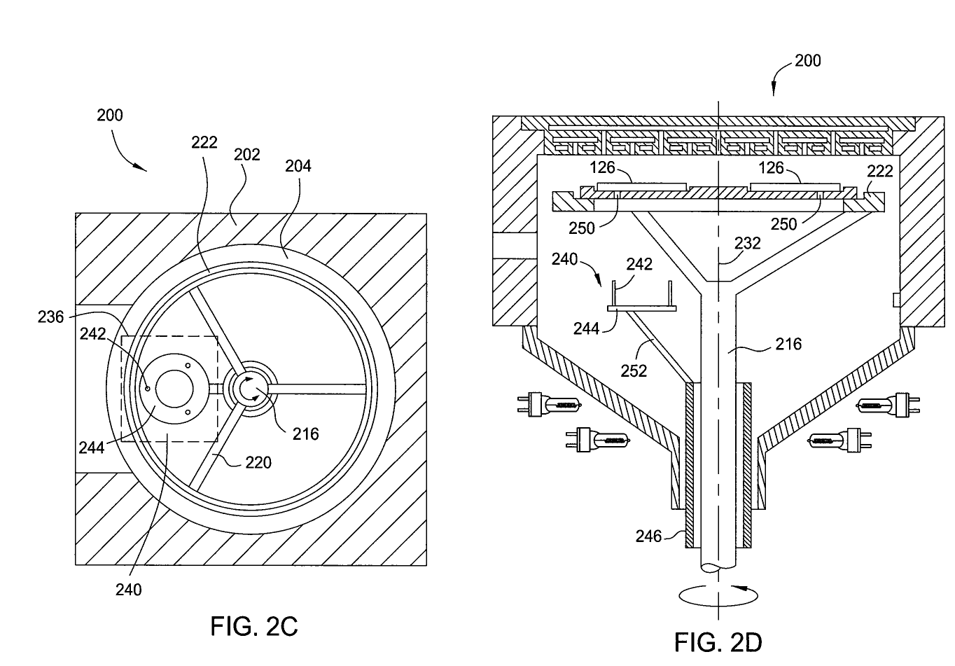

FIGS. 4A and 4B are partial sectional side views of a substrate supporting tray 400 having cover caps 402 for covering through holes 404 in each substrate pocket 408. The through holes 404, similar to pin holes 250 in the substrate supporting tray 214 and through holes 334 in the substrate supporting tray 330, are configured to allow passage of lift pins or grabbing fingers 406. When a lift pin or grabbing finger 406 is lifted through the through hole 404, the cover cap 402 is lifted away from the substrate supporting tray 400 for substrate exchange. During processing, the cover cap 402 plugs the through hole 404 and preventing the substrate 126 from direct heating in the areas exposed by the through holes 404. In one embodiment, the cover cap 402 may be fabricated so that the thermal properties of the cover cap 402 with a thickness of t₁ are similar to the substrate supporting tray 400 with a thickness of t₂.

While the substrate supporting trays 214, 330, and 400 described above can be designed to use in a processing chamber for processing substrates with relatively large size, such as 4 inch, 6 inch, 8 inch or lager substrates, the substrate supporting trays according to embodiments of the present invention may be modified to backward compatible with small substrate processing.

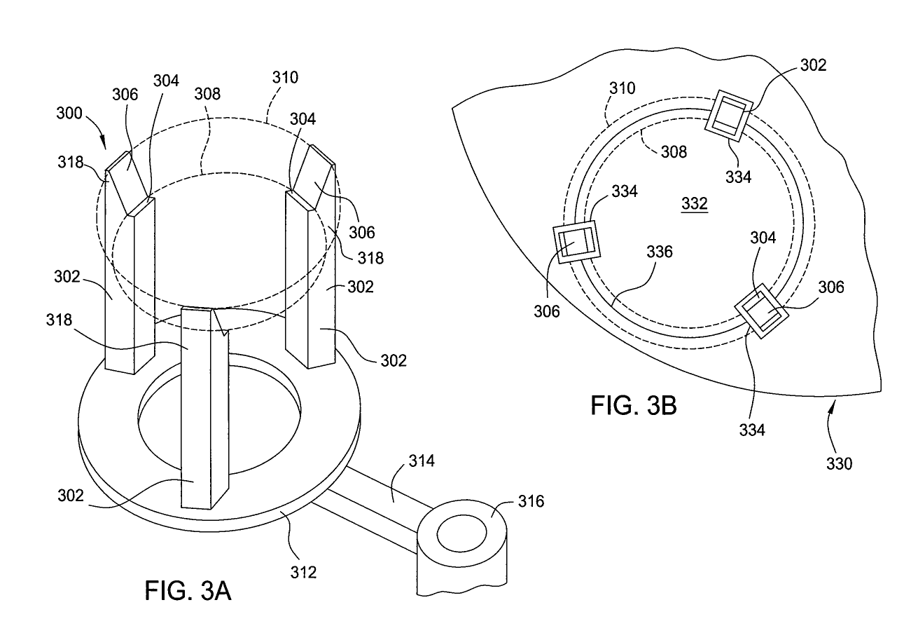

In one embodiment, smaller substrates may be transferred with a sub-carrier. FIG. 5A is a schematic top view of a substrate supporting tray 500 with sub-carriers 504 to process small substrates 506. FIG. 5B is a partial sectional view of the substrate supporting tray 500. Each sub-carrier 504 is configured to support and secure a plurality of small substrates 506. The sub-carrier 504 fits in substrate pockets 502 formed in the substrate supporting tray 500. During processing, the sub-carrier 504 is transferred along with the small substrates 506.

Substrate supporting trays and robot blades according to embodiments for the present invention may be changed to process substrates of different sizes.

Segmented loading/unloading according to embodiments of the present invention may be achieved using various substrate transfer robots. In one embodiment shown in FIGS. 1 and 2A, the substrate transfer robot 114 in the transfer chamber 112 includes one robot blade 130 for handling one substrate.

In another embodiment, the substrate transfer robot 114 may include multiple robot blades each for carrying one substrate at a time. For example, the substrate transfer robot 114 may have two robot blades 130 positioned in two vertical levels. For example, in the substrate transfer robot 114 shown in FIG. 2B, a second robot blade 260 (shown in dashed lines) may be used in combination of the robot blade 130. Substrate pockets in the robot blades 130, 260 may have the same arrangement so that the substrate transfer robot 114 can unload and load a segment of a substrate supporting tray in one trip.

In one embodiment, the robot blades 130, 260 may have may enter the multiple substrate processing chamber 200 at a staggered manner so that lift pins 242 can have access to either robot blade 130, 260 without affecting the other.

During operation, one robot blade 130 or 260 carries one or more substrates to be loaded to the multiple substrate processing chamber 200 while the other blade remains empty. Usually, the robot blade that enters the processing chamber first remains empty so that the multiple substrate processing chamber 200 can be unloaded before loading. In the embodiment of FIG. 2B, the upper robot blade 260 stays empty before operation and the lower robot blade 130 holds one or more substrates to be loaded. The multiple substrate processing chamber 200 has one segment of the substrate supporting tray 214 in the loading position 236, and the lift pins 242 lift up the one or more substrates 126 to be unloaded. The empty robot blade 260 picks up the substrate from the lift pin 242 as the lift pins 242 drop down. The lower robot blade 130 then moves forward to the loading position 236. The lift pins 242 rise to pick up the substrate on the lower robot blade 130 to complete loading of the segment.

Alternatively, the substrate transfer robot 114 may include one robot blade configured to carry two or more substrates at a time.

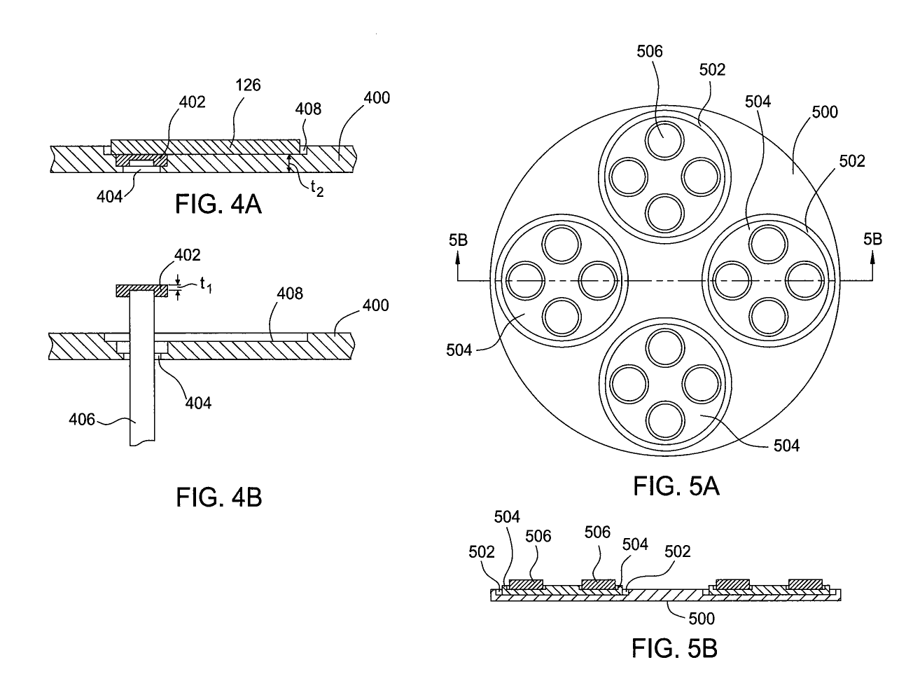

FIG. 6 is a schematic top view of a substrate processing system 600 having a substrate transfer robot 602 for transfer two substrates simultaneously in accordance with one embodiment of the present invention. The substrate processing system 600 may include a transfer chamber 604 having a transfer volume 606. The substrate transfer robot 602 is disposed in the transfer volume 606.

The substrate transfer robot 602 includes a robot blade 608 has two substrate pocket 610 for supporting two substrates thereon. The substrate transfer robot 602 operates to extend the robot blade 608 from the transfer volume 606 in the transfer chamber 604 to processing chambers 612, 614 attached to the transfer chamber 604 through the openings 616, 618 to pick up or drop off substrates. The substrate pockets 610 on the robot blade 608 are arranged to match the arrangement of lift pins 620, 622 in the processing chambers 612, 614.

The processing chambers 612, 614 may have different configurations and capacities as long as each processing chamber 612, 614 includes segments having the same substrate pocket arrangement as of the robot blade 608. The processing chambers 612, 614 include lift pins that match the robot blade 608. The processing chambers 612, 614 may include substrate supporting trays 628, 630 respectively. The substrate supporting trays 628, 630 may include substrate pockets 624, 626. The substrate pockets 624, 626 may be grouped into multiple segments and each segment includes substrate pockets 624, 626 formed in a pattern matching the pattern of the substrate pockets 610 of the robot blade. In the embodiment shown in FIG. 6, the substrate pockets 610 are arranged side by side. The substrate supporting tray 628 may include four segments separated by lines 632, 634. The substrate supporting tray 630 may include two segments formed by line 636.

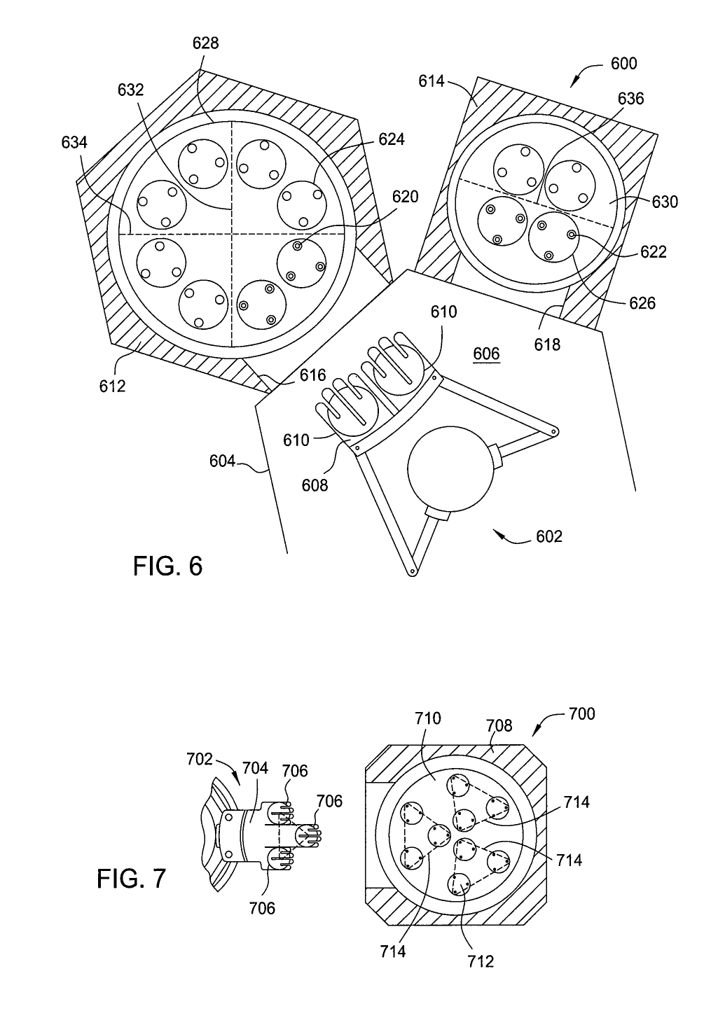

FIG. 7 is a schematic top view of a substrate processing system 700 having a substrate transfer robot 702 for transfer three substrates simultaneously in accordance with one embodiment of the present invention. The transfer robot 702 has a robot blade 704 which includes three substrate pockets 706. The substrate pockets 706 are arranged in the same pattern as substrate pockets 712 within a segment 714 of a substrate supporting tray 710 in a processing chamber 708.

It should be noted that substrate supporting trays and robot blades may have other configurations to allow multiple substrate handling. Robot blades on a substrate transfer robot can be exchanged according to size of the substrates being processed.

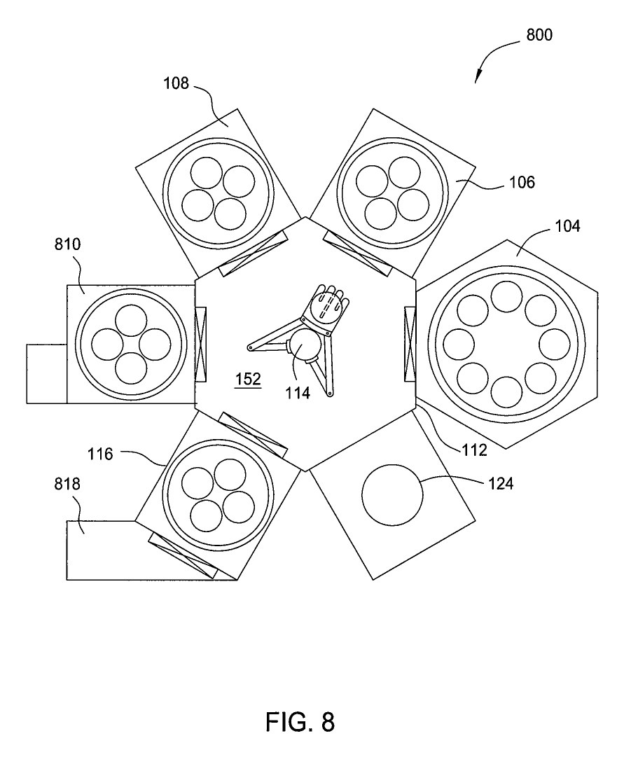

Embodiment of the present invention also includes cluster tools of various configurations with segmented loading function for various process requirements. FIGS. 8-10 illustrate a few exemplary cluster tools according to embodiments of the present invention.

FIG. 8 is a plan view of a cluster tool 800 in accordance with one embodiment of the present invention. The cluster tool 800 is similar to the cluster tool 100 of FIG. 1 except that a HVPE chamber 810 is connected to the transfer chamber 112 in place of the processing chamber 110, and a loading station 818 instead of the factory interface 118 is connected to the load lock chamber 116.

The cluster tool 800 includes processing chambers 104, 106, 108 configured for performing MOCVD processes, and the HVPE chamber 810. Each chamber 104, 106, 108, 810 can be segmented loaded by the substrate transfer robot 114 disposed in the transfer chamber 112.

The HVPE chamber 810 and the processing chambers 106, 108 may have the same substrate processing capacities while the processing chamber 104 can process twice as many substrates as the chambers 810, 106, 108. The HVPE chamber 810 increases the efficiency of the cluster tool by using a HVPE process to increase growth rate from the MOCVD deposition. The HVPE chamber 810 may be used in forming n-GaN layers in metal nitride devices.

According to one embodiment of the present invention, the cluster tool 800 is configured to form LED devices. The HVPE chamber 810 is configured to form n-GaN layers for LED devices; the processing chambers 106, 108 are MOCVD chambers configured to form MQW layers; and the processing chamber 104 is a MOCVD chamber configured to form p-GaN layers.

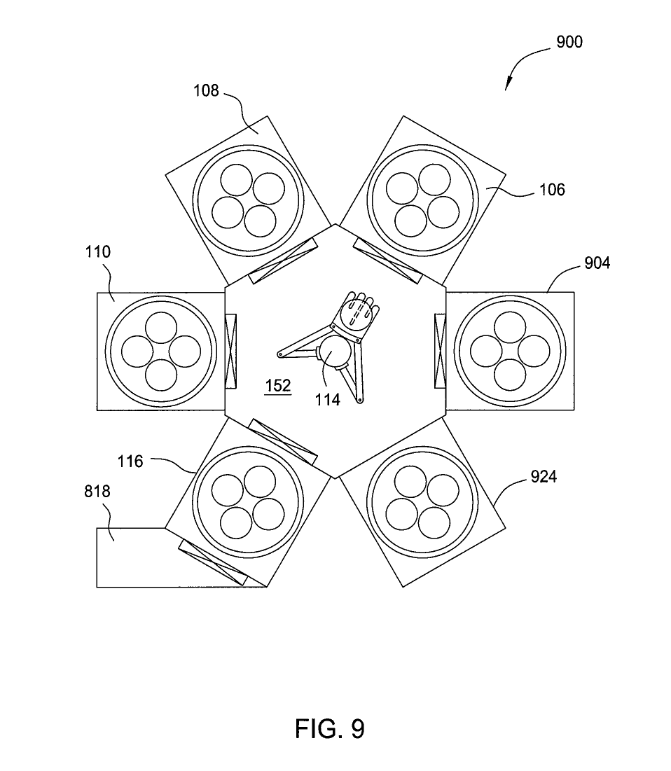

FIG. 9 is a plan view of a cluster tool 900 in accordance with another embodiment of the present invention.

The cluster tool 900 is similar to the cluster tool 100 of FIG. 1 except that there is a fifth processing chamber 924 connected to the transfer chamber 112 in place of the service chamber 124, all five processing chambers 106, 108, 110, 904, 924 have the same substrate processing capacity, and a loading station 818 instead of the factory interface 118 is connected to the load lock chamber 116.

In one embodiment, all five processing chambers 106, 108, 110, 904, 924 are MOCVD chamber. The cluster tool 900 may be configured to form LED devices. For example, the processing chambers 110, 108 are configured to form n-GaN layers for LED devices; the processing chambers 106, 904 are configured to form MQW layers; and the processing chamber 924 is configured to form p-GaN layers.

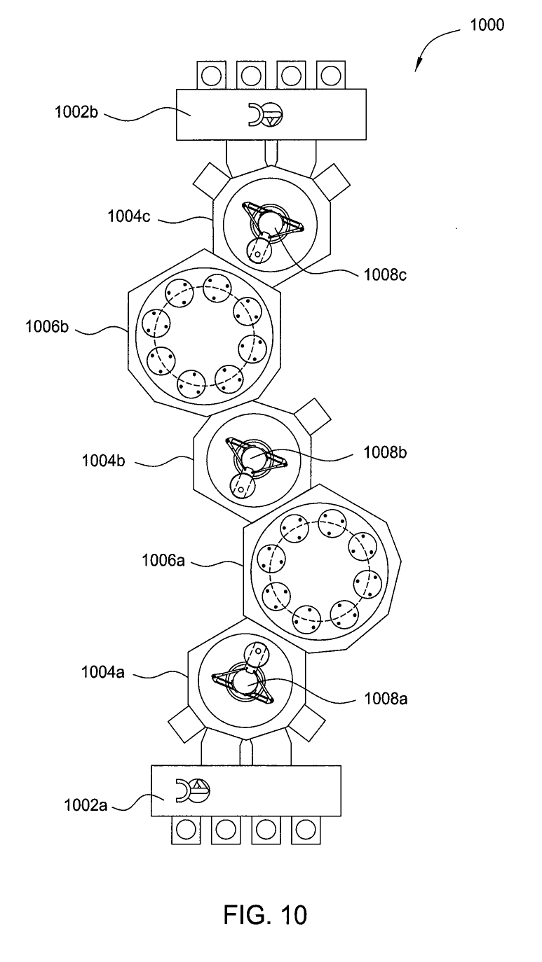

FIG. 10 is a plan view of a linear cluster tool 1000 for multiple-substrate processing in accordance with one embodiment of the present invention.

The cluster tool 1000 includes two factory interfaces 1002a, 1002b with a plurality of transfer chambers 1004a, 1004b, 1004c and processing chambers 1006a, 1006b connected in between. During processing, substrates being processed enter the cluster tool 1000 from the factory interface 1002a, go through the transfer chambers 1004a, 1004b, 1004c to be processed in the processing chambers 1006a, 1006b sequentially, and exit the cluster tool 1000 from the factory interface 1002b. The processing chamber 1006a, 1006b can be loaded/unloaded segmented by substrate transfer robots 1008a, 1008b, 1008c in the transfer chambers 1004a, 1004b, 1004c.

Each processing chamber 1006a, 1006b in the cluster tool 1000 is connected to two transfer chambers. This configuration further increases loading and unloading efficiency because loading and unloading can be performed simultaneously by two substrate transfer robots in the two transfer chambers. The processing chamber 1006a, 1006b may have two loading positions and two lift pin assemblies for the two robots.

The segmented loading arrangement according to embodiments of the present invention provides several advantages and improvements to cluster tools, such as the cluster tools 100, 800, 900, and 1000.

One advantage is improving repeatability of a multiple-substrate processing chamber. Because segmented loading allows the substrate supporting trays to become permanent structures in processing chambers, the stability of the processing environment in the processing chambers improves and performance repeatability also improves.

Another advantage of segmented loading arrangement is avoiding transferring substrate supporting trays with the substrates during processing. When transferring substrates in substrate supporting trays, the substrate supporting tray is usually designed to be suitable for various processing chambers simultaneously in a cluster tool since the substrate supporting tray travels through the various processing chambers with the substrates. Thus, designs of the substrate supporting tray may be compromised to fit different chambers. In the segmented loading arrangement, each substrate supporting tray remains in the corresponding processing chamber and can have individual designs to best suit the particular processing chamber. Furthermore, when transferring substrates in substrate supporting trays, process variation from load to load can be introduced by the manufacturing tolerance of the substrate supporting trays. Segmented loading arrangement eliminates process variations from load to load caused by the substrate supporting trays.

Another advantage is increasing productivity. By incorporating segmented loading/unloading without transferring substrate supporting trays with the substrates, larger processing chamber can be used since the chamber size is no longer limited by the size of the substrate supporting tray, or the size of the slit valve opening, or the range of motion of substrate transfer robots. Larger processing chambers process a larger number of substrates, thus increasing overall productivity of a cluster tool.

Using segmented loading also allows a cluster tool to include chambers of different dimensions or substrate processing capacities. A cluster tool may use a large processing chamber for a long process, and a small processing chamber for a short process, thus, optimizing the cluster tool between efficiency and cost.

Using segmented loading in a cluster tool also reduces cost by avoiding costs for manufacturing and maintaining substrate supporting trays that travel with substrates during processing. Additionally, using segmented loading also simplifies substrate handling systems by only using robots for handling substrates, and deleting the robots for handling substrate supporting trays, thus, further reduce operation costs.

Furthermore, segmented loading also reduces cross contamination among processing chambers caused by substrate supporting trays moving from chamber to chamber during operation.

Although, manufacturing LED is described above, other embodiments of the present invention are suitable for any processes where multiple-substrate process is performed. Embodiments of the present invention are also suitable of loading and unloading a standalone multiple-substrate processing chamber.

While the foregoing is directed to embodiments of the present invention, other and further embodiments of the invention may be devised without departing from the basic scope thereof, and the scope thereof is determined by the claims that follow.

What is claimed is:

1. An apparatus for processing multiple substrates, comprising:
a chamber body defining a processing volume, wherein the chamber body has a first opening to allow passage of substrates therethrough;
a substrate supporting tray disposed in the processing volume, wherein the substrate supporting tray has a plurality of substrate pockets formed on an upper surface, each substrate pocket accommodates a substrate therein, and the plurality of substrate pockets form a plurality of segments; and
a substrate handling assembly disposed in the processing volume, wherein the substrate handling assembly moves relative to the substrate supporting tray to pick up and drop off substrates from and to a segment of substrate pockets in a loading position aligned with the substrate handling assembly, and each of the plurality of segments is alignable with the substrate handling assembly.

2. The apparatus of claim 1, wherein the substrate handling assembly comprises one of a vacuum chuck, a Bernoulli chuck, an electrostatic chuck or three or more grabbing fingers configured to grab an edge of a substrate being handled.

3. The apparatus of claim 2, wherein the substrate handling assembly comprises three or more lift pins disposed under the substrate supporting tray near the first opening in the chamber body, and each substrate pocket has three or more pins holes formed through the substrate supporting tray for the three or more lift pins to be inserted.

4. The apparatus of claim 3, wherein each segment comprises one substrate pocket, and the plurality of substrates are arranged in a circle.

5. The apparatus of claim 3, wherein each segment comprises one or more substrate pockets, and the substrate pockets are arranged in the same pattern in each segments.

6. The apparatus of claim 5, wherein each segment comprises three substrate pockets.

7. The apparatus of claim 5, where each segment is alignable with the three or more lift pins by rotating the substrate supporting tray about a central axis of substrate supporting tray.

8. The apparatus of claim 3, further comprising a second substrate handling assembly disposed under the substrate supporting tray near a second opening formed through the chamber body, wherein the second substrate handling assembly is configured to pick up and drop off substrates from and to a segment of substrate pockets of the substrate supporting tray.

9. The apparatus of claim 3, wherein the substrate supporting tray comprises three or more cover caps in each substrate pocket, and each cover cap removably disposed in a corresponding pin hole.

10. A cluster tool for processing multiple substrates, comprising:
a first processing chamber comprising:
a chamber body defining a first processing volume, wherein the chamber body has a first opening configured to allow passage of substrates therethrough;
a first substrate supporting tray disposed in the processing volume, wherein the first substrate supporting tray has a plurality of substrate pockets formed on an upper surface, each substrate pocket accommodates a substrate therein, and the plurality of substrate pockets form a plurality of segments; and
a first substrate handling assembly disposed in the first processing volume, wherein the first substrate handling assembly moves relative to the first substrate supporting tray to pick up and drop off substrates from and to a segment of substrate pockets of the first substrate supporting tray;
a transfer chamber selectively connected to the first processing chamber via the first opening of the first processing chamber; and
a substrate transfer robot disposed in the transfer chamber to load and unload substrates in the first processing chamber, wherein the substrate transfer robot includes a first robot blade having one or more substrate pockets, the one or more substrate pockets in the first robot blade are arranged in the same pattern as the one or more substrate pockets in each segment on the first substrate supporting tray of the first processing chamber.

11. The cluster tool of claim 10, further comprising a second processing chamber connected to the transfer chamber, wherein the second processing chamber comprises a second substrate supporting tray having a plurality of substrates forming multiple segments, and the substrate pockets in each segment in the second substrate supporting tray are arranged in the same pattern as the substrate pockets on the first robot blade.

12. The cluster tool of claim 11, wherein the substrate transfer robot further comprises a second robot blade having one or more substrate pockets arranged in the same pattern as the one or more substrate pockets in the first robot blade, and the first robot blade and the second robot blade are alignable with a segment on first or second substrate supporting tray independently.

13. The cluster tool of claim 11, further comprising:
a third processing chamber connected to the transfer chamber, wherein the third processing chamber comprises a third substrate supporting tray having a plurality of substrates forming multiple segments, and the substrate pockets in each segment in the third substrate supporting tray are arranged in the same pattern as the substrate pockets on the first robot blade; and
a fourth processing chamber connected to the transfer chamber, wherein the fourth processing chamber comprises a fourth substrate supporting tray having a plurality of substrates forming multiple segments, and the substrate pockets in each segment in the fourth substrate supporting tray are arranged in the same pattern as the substrate pockets on the first robot blade.

14. The cluster tool of claim 13, wherein the number of substrate pockets on first substrate supporting tray is twice as many as the numbers of substrate pockets on the second substrate supporting tray.

15. The cluster tool of claim 14, wherein:
the first processing chamber is a MOCVD (metal organic chemical mechanical deposition) chamber configured to form an n-GaN (n-doped GaN) layer;
the second processing chamber is a MOCVD chamber configured to form a MQW (multi-quantum well) layer;
the third processing chamber is a MOCVD chamber configured to form a MQW (multi-quantum well) layer; and
the forth processing chamber is a MOCVD chamber configured to form a p-GaN (p-doped GaN) layer.

16. The cluster tool of claim 14, wherein:
the first processing chamber is a MOCVD (metal organic chemical mechanical deposition) chamber configured to form a MQW layer;
the second processing chamber is a HVPE (hydride vapor phase epitaxy) chamber configured to form an n-GaN layer;
the third processing chamber is a MOCVD chamber configured to form a p-GaN layer; and
the forth processing chamber is a MOCVD chamber configured to form a p-GaN layer.

17. The cluster tool of claim 13, further comprising:
a fifth processing chamber connected to the transfer chamber, wherein the fifth processing chamber comprises a fifth substrate supporting tray having a plurality of substrates forming multiple segments, and the substrate pockets in each segment in the fifth substrate supporting tray are arranged in the same pattern as the substrate pockets on the first robot blade,
wherein:
the first processing chamber is a MOCVD chamber configured to form an n-GaN layer;
the second processing chamber is a MOCVD chamber configured to form an n-GaN layer;
the third processing chamber is a MOCVD chamber configured to form a MQW layer;
the fourth processing chamber is a MOCVD chamber configured to form a MQW layer; and
the fifth processing chamber is a MOCVD chamber configured to form a p-GaN layer.

18. The cluster tool of claim 10, further comprising:
a second transfer chamber connected to the first processing chamber, wherein the first processing chamber has a second opening, and the second transfer chamber is selectively connected to the first processing chamber via the second opening.

19. A method for handling substrates during multiple-substrate processing, comprising:
receiving one or more substrates in a first segment of a substrate supporting tray in a multiple-substrate processing chamber from an exterior substrate transfer robot, wherein the multiple-substrate processing chamber comprises:
a chamber body defining a processing volume, wherein the chamber body has a first opening to allow passage of substrates therethrough;
the substrate supporting tray disposed in the processing volume, wherein the substrate supporting tray has a plurality of substrate pockets formed on an upper surface, each substrate pocket accommodates a substrate therein, and the plurality of substrate pockets form a plurality of segments; and
a substrate handling assembly disposed in the processing volume, wherein the substrate handling assembly moves relative to the substrate supporting tray to pick up and drop off substrates from and to a segment of substrate pockets in a loading position aligned with the substrate handling assembly, and each of the plurality of segments is alignable with the substrate handling assembly;
rotating the substrate supporting tray to align a second segment of the substrate supporting tray with the substrate handling assembly; and
receiving one or more substrates in the second segment of the substrate supporting tray from the exterior substrate transfer robot.

20. The method of claim 19, wherein receiving one or more substrates in the first segment of the substrate supporting tray comprises:
rotating the substrate supporting tray to align the first segment with the substrate handling assembly;
inserting three or more lift pins from the substrate handling assembly through pin holes formed through the substrate pockets in the first segment;
receiving the one or more substrates from the exterior substrate transfer robot on the three on more lift pins; and
removing the three or more lift pins from the substrate supporting tray to drop the one or more substrates in the substrate pockets in the first segment of the substrate supporting tray.
